(19) United States
(12) Patent Application Publication
(10) Pub. No.: US 2007/0200169 A1
(43) Pub. Date: Aug. 30, 2007

(54) Gate electrode of semiconductor device and method for fabricating the same

(75) Inventor: Kwang-Ok Kim, Kyoungki-do (KR)

Correspondence Address: LOWE HAUPTMAN BERNER, LLP, 1700 DIAGONAL ROAD, SUITE 300, ALEXANDRIA, VA, 22314, US

(73) Assignee: Hynix Semiconductor Inc.

(21) Appl. No.: 11/633,055

(22) Filed: Dec. 4, 2006

(30) Foreign Application Priority Data
Feb. 28, 2006 (KR) 10-2006-0019682

(51) Int. Cl. H01L 29/78; H01L 21/4763

(52) U.S. Cl. 257/330; 438/488; 438/589

(57) ABSTRACT

A gate electrode of a semiconductor device according to the present invention includes a substrate, a bulb type recess with an upper recess and a bottom recess, the bottom recess formed in a round shape and having a larger width than the upper recess, a gate insulation layer formed over the substrate and in the bulb type recess, and a polysilicon electrode in the bulb type recess, wherein the polysilicon electrode is formed using two different methods including a growth method

### FIELD OF THE INVENTION

The present invention relates to a method for fabricating a semiconductor device, and more particularly, to a method for fabricating a gate electrode in a semiconductor device.

### DESCRIPTION OF RELATED ARTS

As semiconductor devices have become highly integrated, the gate channel length has decreased and the ion implantation doping concentration level has increased, resulting in an increased electric field. The increased electric field generates junction leakage. Thus, it has become difficult to maintain a refresh characteristic of the device due to the junction leakage during a typical planar gate line formation method, where gates are formed over a planarized active region.

A recess gate process has been performed as an improved gate line formation method to overcome the above described limitation. The recess gate process includes etching an active region of the substrate to form a recess pattern and then forming a gate. Performing the recess gate process allows an increase in a gate channel length and a decrease in an ion implantation doping concentration level, resulting in an improved refresh characteristic of the device. However, the device is becoming even more highly integrated, and there exists a limitation in the increase of the recess gate depth.

Therefore, a method for forming a bulb type recess has been introduced. The bulb type recess includes a rounded bottom portion having a wider width than an upper portion.

FIG. 1 illustrates a cross-sectional view of a typical semiconductor device. Device isolation structures 12 are formed in a substrate 11, and gate patterns are buried in the substrate 11. Reference numeral 14 denotes a gate insulation layer. Each gate pattern includes: a bulb type recess formed in the substrate; a polysilicon electrode 15 filled in the bulb type recess; and a metal electrode 16 and a nitride-based gate hard mask 17 formed over the polysilicon electrode 15. Each bulb type recess is configured with an upper recess 13A and a bottom recess 13B. The bottom recess 13B is rounded and has a larger width than the upper recess 13A. The polysilicon electrodes 15 filled in the bulb type recesses are formed by performing a chemical vapor deposition (CVD) method.

However, when the CVD method is used, the polysilicon electrodes 15 may not completely fill the bulb type recesses and thus voids 100 may be generated. The voids 100 often causes limitations in device operation reliability, and the polysilicon electrodes 15 may not be able to sufficiently function as gate electrodes due to the stress concentrated in the irregularly formed polysilicon electrodes 15.

### SUMMARY OF THE INVENTION

It is, therefore, an object of the present invention to provide a semiconductor device and a method for fabricating the same, which can prevent a polysilicon electrode from insufficiently filling a recess, and consequently, prevent generations of voids while forming a bulb type recess.

In accordance with an aspect of the present invention, there is provided a semiconductor device, including: a substrate; a bulb type recess with an upper recess and a bottom recess, the bottom recess formed in a round shape and having a larger width than the upper recess; a gate insulation layer formed over the substrate and in the bulb type recess; and a polysilicon electrode in the bulb type recess, wherein the polysilicon electrode is formed using two different methods including a growth method.

In accordance with another aspect of the present invention, there is provided a method for fabricating a semiconductor device, including: selectively etching a portion of a substrate to form a bulb type recess with an upper recess and a bottom recess, the bottom recess formed in a round shape and having a larger width than the upper recess; forming a gate oxide layer over the substrate and in the bulb type recess; and forming a polysilicon electrode in the bulb type recess using two different types of methods including a growth method.

### BRIEF DESCRIPTION OF THE DRAWINGS

The above and other objects and features of the present invention will become better understood with respect to the following description of the exemplary embodiments given in conjunction with the accompanying drawings, in which:

FIG. 1 illustrates a cross-sectional view of a typical semiconductor device;

FIGS. 2A to 2D illustrate cross-sectional views to describe a method for fabricating a semiconductor device consistent with a first embodiment of the present invention;

FIGS. 3A to 3E illustrate cross-sectional views to describe a method for fabricating a semiconductor device consistent with a second embodiment of the present invention;

FIGS. 4A to 4D illustrate cross-sectional views to describe a method for fabricating a semiconductor device consistent with a third embodiment of the present invention;

FIGS. 5A to 5D illustrate cross-sectional views to describe a method for fabricating a semiconductor device consistent with a fourth embodiment of the present invention; and

FIGS. 6 to 9 illustrate cross-sectional views of a semiconductor device consistent with an embodiment of the present invention.

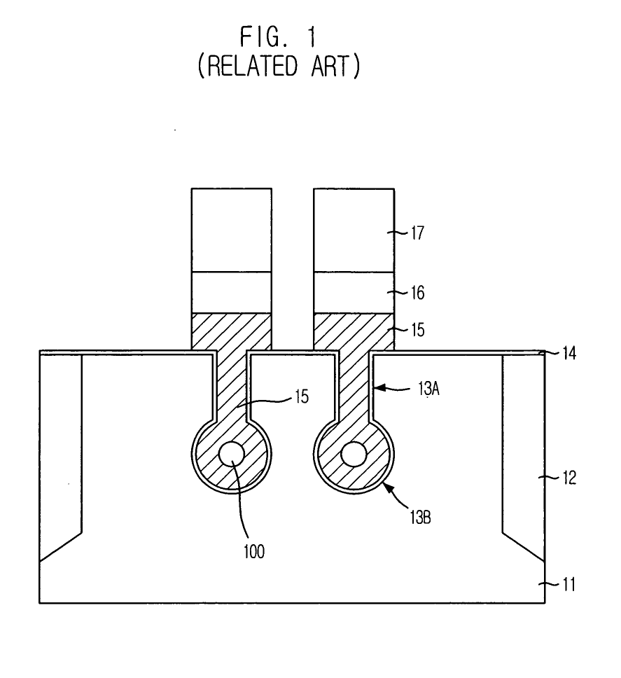

### DETAILED DESCRIPTION OF THE INVENTION

A gate electrode of a semiconductor device and a method for fabricating the same in accordance with exemplary embodiments of the present invention will be described in detail with reference to the accompanying drawings.

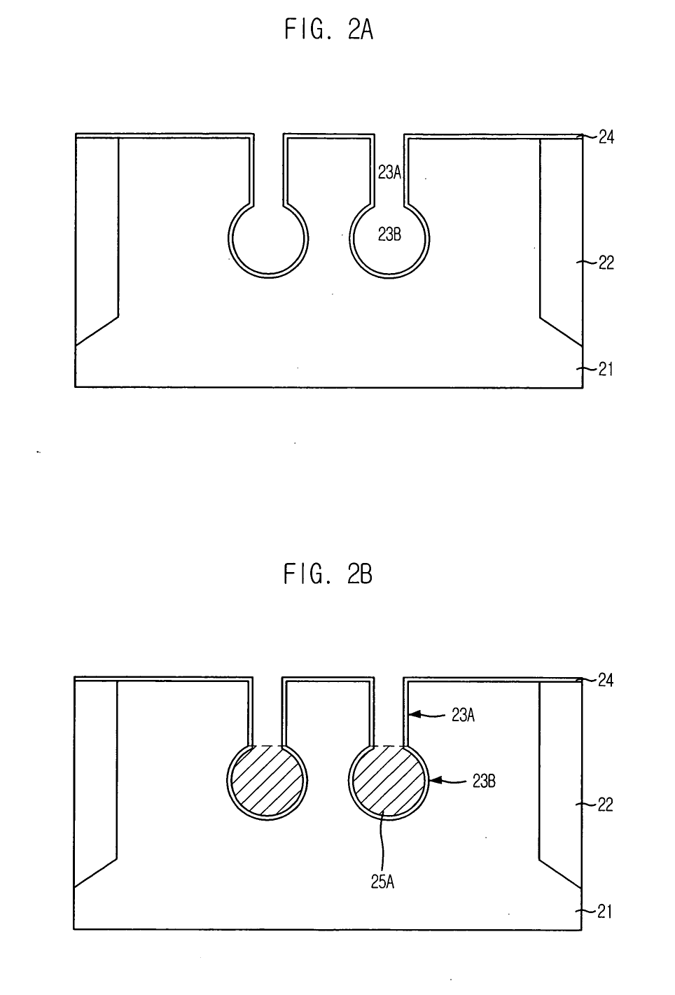

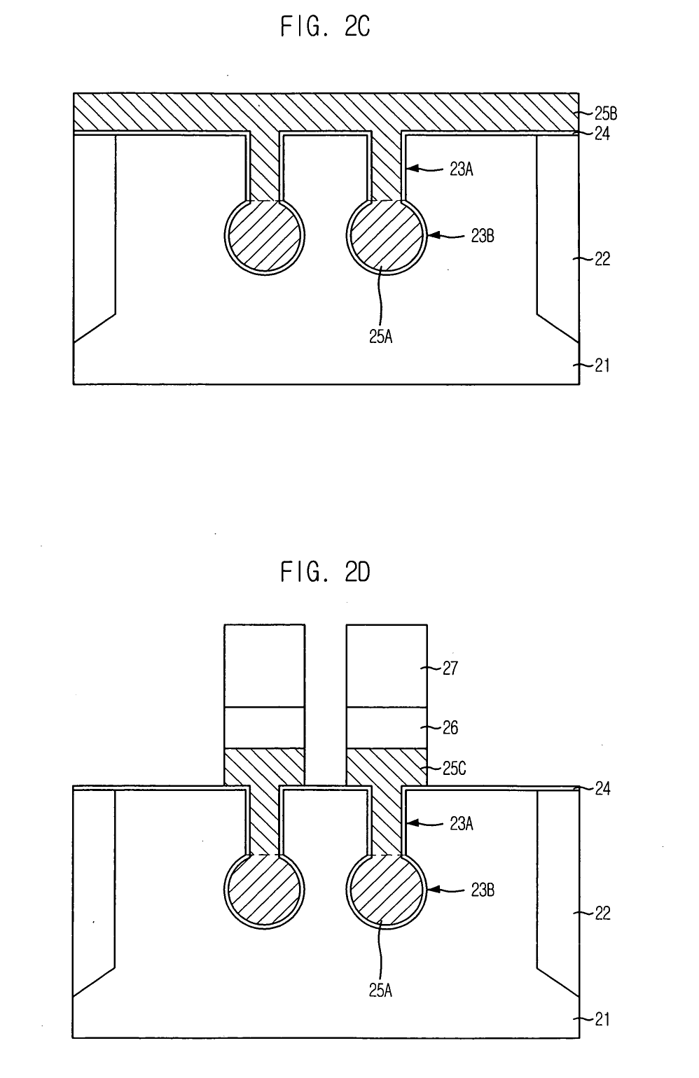

FIGS. 2A to 2D illustrate cross-sectional views to describe a method for fabricating a semiconductor device consistent with a first embodiment of the present invention.

Referring to FIG. 2A, device isolation structures 22 are formed in a substrate 21. The device isolation structures 22 are formed to define an active region and have a larger depth than subsequent recesses. Portions of the substrate 21 are selectively etched to form bulb type recesses. The bulb type recesses have a vertical profile, and each bulb type recess is configured with an upper recess 23A and a bottom recess 23B. Each bottom recess 23B is formed in a round shape and has a larger width than the upper recess 23A. Forming the bottom recess 23B having the larger width than the upper recess 23A allows maintaining a longer channel length when compared to a typical ‘U’ type recess having substantially the same depth as the bulb type recess consistent with this embodiment. A gate insulation layer 24 is formed over the substrate 21 and the device isolation structures 22, and in the bulb type recesses.

Referring to FIG. 2B, first polysilicon electrodes 25A are filled in the bottom recesses 23B. The first polysilicon electrodes 25A are formed by performing a solid phase epitaxy (SPE) method. Performing the SPE method includes forming a silicon seed layer and growing the silicon seed layer.

Thus, the first polysilicon electrodes 25A may be formed in the bottom recesses 23B without generating voids by growing a seed layer unlike typical deposition methods often generating voids due to a depth or width.

Referring to FIG. 2C, a second polysilicon electrode layer 25B is formed over the resultant substrate structure and filled in the upper recesses 23A. The second polysilicon electrode layer 25B is formed by performing a chemical vapor deposition (CVD) method.

A sufficient level of deposition margin is maintained because the first polysilicon electrodes 25A are formed in the bottom recesses 23B in advance using the SPE method. Thus, the second polysilicon electrode layer 25B may be formed without generating voids using the typical CVD method.

The second polysilicon electrode layer 25B, which is the uppermost layer of the resultant substrate structure, has a uniformly formed surface since the second polysilicon electrode layer 25B is formed by the CVD method. Thus, process simplification may be achieved because a chemical mechanical polishing (CMP) process is not required.

Referring to FIG. 2D, gate patterns are formed, partially buried in the upper and bottom recesses 23A and 23B. Each gate pattern is configured with a gate hard mask 27, a metal electrode 26, a second polysilicon electrode 25C, and the first polysilicon electrode 25A. In more detail, a metal electrode layer and a gate hard mask layer are sequentially formed over the second polysilicon electrode layer 25B. The gate hard mask layer includes a nitride-based material. The gate hard mask layer, the metal electrode layer, and the second polysilicon electrode layer 25B are patterned to form the gate hard masks 27, the metal electrodes 26, and the second polysilicon electrodes 25C. The metal electrodes 26 may include one of tungsten and tungsten silicide.

The deposition margin may be maintained since the SPE method growing silicon is performed to form the first polysilicon electrodes 25A in the bottom recesses 23B. Thus, the first and second polysilicon electrodes 25A and 25C may be formed without generating voids even when the second polysilicon electrodes 25C are formed in the upper recesses 23A using the typical CVD method.

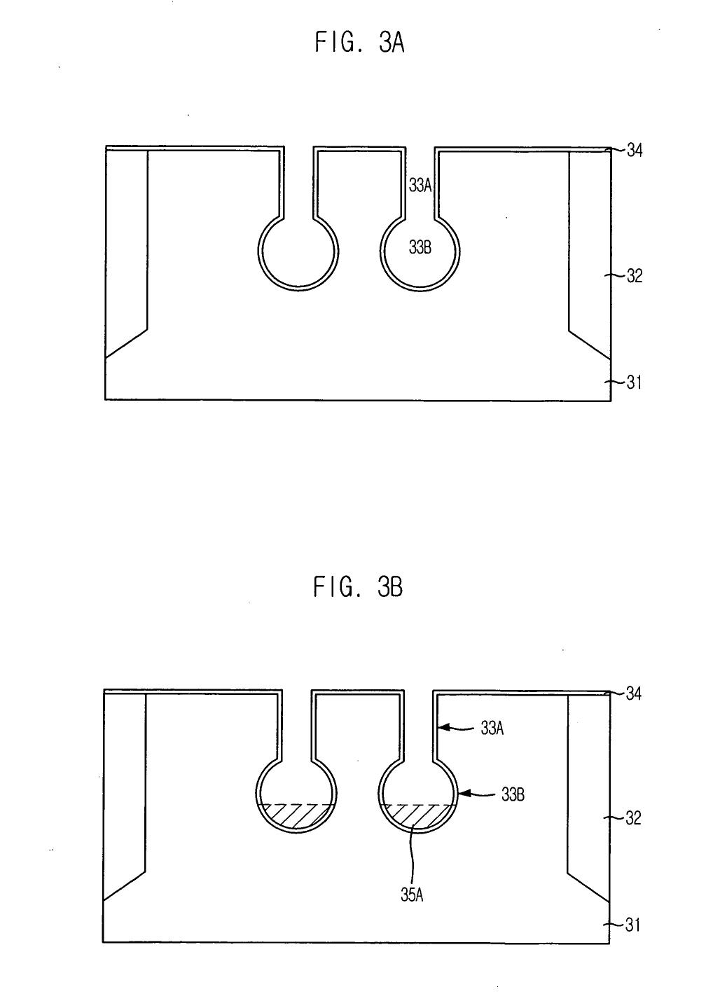

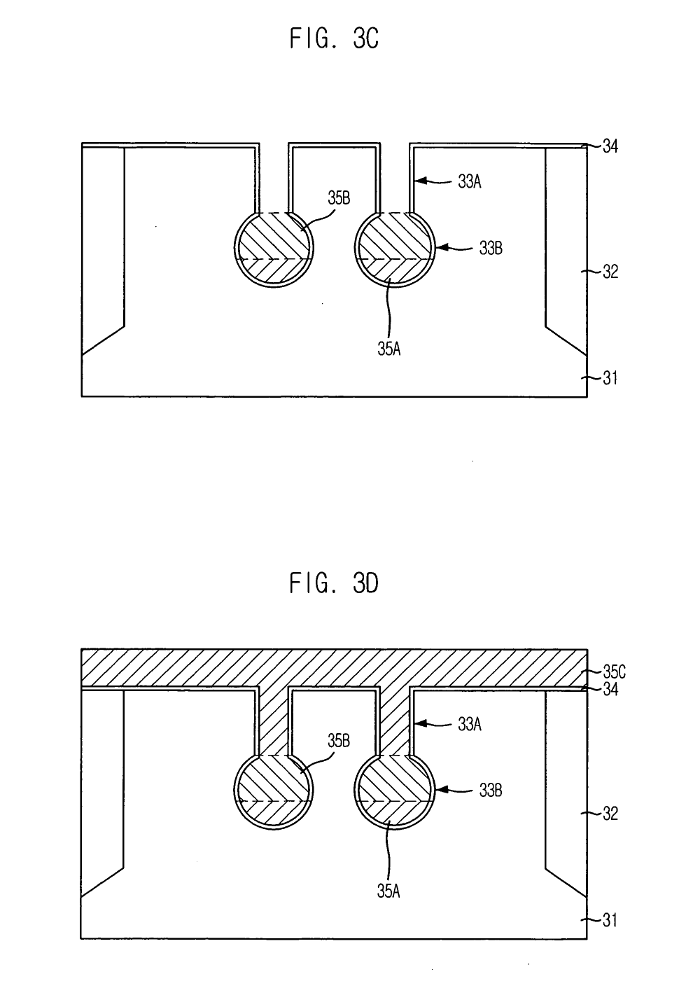

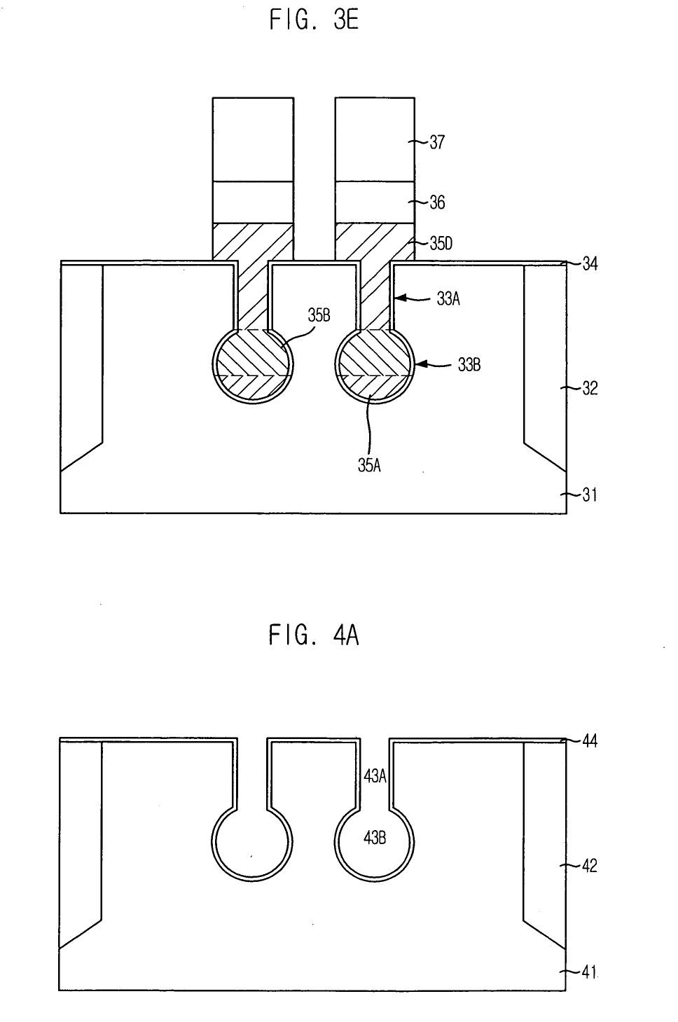

FIGS. 3A to 3E illustrate cross-sectional views to describe a method for fabricating a semiconductor device consistent with a second embodiment of the present invention.

Referring to FIG. 3A, device isolation structures 32 are formed in a substrate 31. The device isolation structures 32 are formed to define an active region and have a larger depth than subsequent recesses. Portions of the substrate 31 are selectively etched to form bulb type recesses. The bulb type recesses have a vertical profile, and each bulb type recess is configured with an upper recess 33A and a bottom recess 33B. Each bottom recess 33B is formed in a round shape and has a larger width than the upper recess 33A. Forming the bottom recess 33B having the larger width than the upper recess 33A allows maintaining a longer channel length when compared to a typical ‘U’ type recess having substantially the same depth as the bulb type recess consistent with this embodiment. A gate insulation layer 34 is formed over the substrate 31 and the device isolation structures 32, and in the bulb type recesses.

Referring to FIG. 3B, first polysilicon electrodes 35A are filled in a portion of the bottom recesses 33B. The first polysilicon electrodes 35A are formed by performing a deposition method, i.e., a CVD method, and yet, voids are not generated because only a portion of the bottom recesses 33B is filled.

For instance, if the bulb type recesses configured with the upper and bottom recesses 33A and 33B has a total depth of approximately 2,000 Å, each of the upper and bottom recesses 33A and 33B has a depth of approximately 1,000 Å, and each first polysilicon electrode 35A fills a depth of approximately 400 Å or less from the bottom of the bottom recess 33B.

Referring to FIG. 3C, second polysilicon electrodes 35B are formed over the first polysilicon electrodes 35A, the second polysilicon electrodes 35B filling the rest of the bottom recesses 33B. The second polysilicon electrodes 35B are formed by performing a SPE method. Thus, the second polysilicon electrodes 35B are formed without voids in the bottom recesses 33B.

Referring to FIG. 3D, a third polysilicon electrode layer 35C is formed over the resultant substrate structure and filled in the upper recesses 33A. The third polysilicon electrode layer 35C is formed by performing a CVD method.

A sufficient level of deposition margin is maintained because the first and second polysilicon electrodes 35A and 35B are formed in the bottom recesses 33B in advance using the deposition method and the SPE method, respectively. Thus, the third polysilicon electrode layer 35C may be formed without generating voids using the typical CVD method.

The third polysilicon electrode layer 35C, which is the uppermost layer of the resultant substrate structure, has a uniformly formed surface since the third polysilicon electrode layer 35C is formed by the CVD method. Thus, process simplification may be achieved because a CMP process is not required.

Referring to FIG. 3E, gate patterns are formed, partially buried in the upper and bottom recesses 33A and 33B. Each gate pattern is configured with a gate hard mask 37, a metal electrode 36, a third polysilicon electrode 35D, the second polysilicon electrode 35B, and the first polysilicon electrode 35A. In more detail, a metal electrode layer and a gate hard mask layer are sequentially formed over the third polysilicon electrode layer 35C. The gate hard mask layer includes a nitride-based material. The gate hard mask layer, the metal electrode layer, and the third polysilicon electrode layer 35C are patterned to form the gate hard masks 37, the metal electrodes 36, and the third polysilicon electrodes 35D. The metal electrodes 36 may include one of tungsten and tungsten silicide.

The deposition margin may be maintained since a portion of the bottom recesses 33B is filled with the first polysilicon electrodes 35A using the deposition method, and the rest of the bottom recesses 33B is filled with the second polysilicon electrodes 35B using the SPE method growing silicon. Thus, the first, second and third polysilicon electrodes 35A, 35B, and 35D may be formed without generating voids even when the third electrodes 35D are formed in the upper recesses 33A using the typical CVD method.

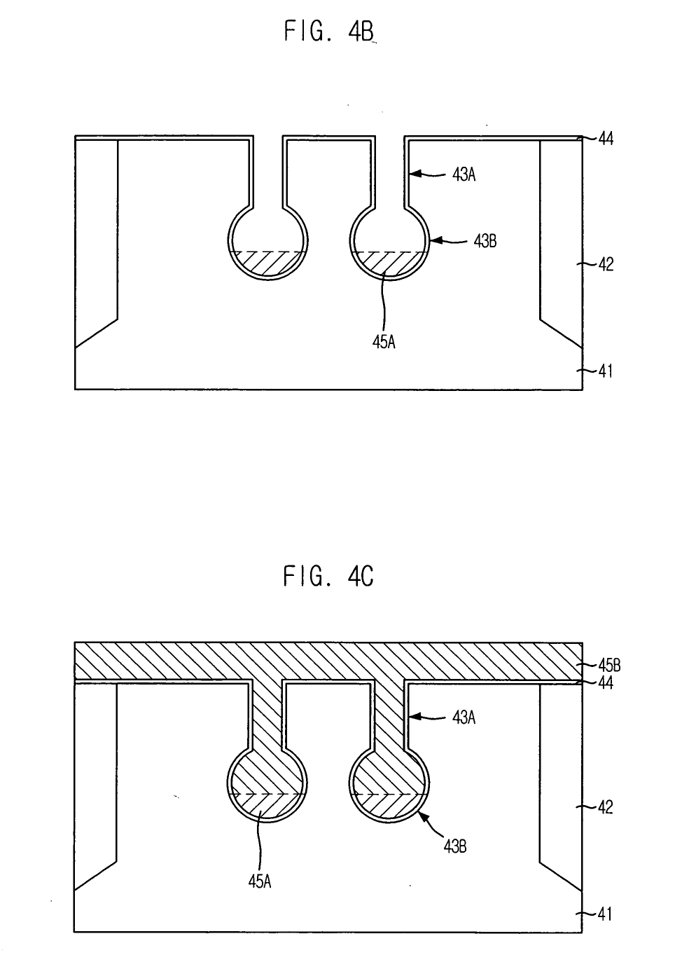

FIGS. 4A to 4D illustrate cross-sectional views to describe a method for fabricating a semiconductor device consistent with a third embodiment of the present invention.

Referring to FIG. 4A, device isolation structures 42 are formed in a substrate 41. The device isolation structures 42 are formed to define an active region and have a larger depth than subsequent recesses. Portions of the substrate 41 are selectively etched to form bulb type recesses. The bulb type recesses have a vertical profile, and each bulb type recess is configured with an upper recess 43A and a bottom recess 43B. Each bottom recess 43B is formed in a round shape and has a larger width than the upper recess 43A. Forming the bottom recess 43B having the larger width than the upper recess 43A allows maintaining a longer channel length when compared to a typical ‘U’ type recess having substantially the same depth as the bulb type recess consistent with this embodiment. A gate insulation layer 44 is formed over the substrate 41 and the device isolation structures 42, and in the bulb type recesses.

Referring to FIG. 4B, first polysilicon electrodes 45A are filled in a portion of the bottom recesses 43B. The first polysilicon electrodes 45A are formed by performing a deposition method, i.e., a CVD method, and yet, voids are not generated because only a portion of the bottom recesses 43B is filled.

For instance, if the bulb type recesses configured with the upper and bottom recesses 43A and 43B has a total depth of approximately 2,000 Å, each of the upper and bottom recesses 43A and 43B has a depth of approximately 1,000 Å, and each first polysilicon electrode 45A fills a depth of approximately 400 Å or less from the bottom of the bottom recess 43B.

Referring to FIG. 4C, a second polysilicon electrode layer 45B is formed over the resultant substrate structure and filled in the rest of the bottom recesses 43B and the upper recesses 43A. The second polysilicon electrode layer 45B is formed by performing a selective epitaxial growth (SEG) method.

The second polysilicon electrode layer 45B is planarized. The second polysilicon electrode layer 45B, which is the uppermost layer of the resultant substrate structure, has an irregularly formed surface because a growth method, i.e., the SEG method, is employed, and thus, planarization is generally required.

Referring to FIG. 4D, gate patterns are formed, partially buried in the upper and bottom recesses 43A and 43B. Each gate pattern is configured with a gate hard mask 47, a metal electrode 46, a second polysilicon electrode 45C, and the first polysilicon electrode 45A. In more detail, a metal electrode layer and a gate hard mask layer are sequentially formed over the second polysilicon electrode layer 45B. The gate hard mask layer includes a nitride-based material. The gate hard mask layer, the metal electrode layer, and the second polysilicon electrode layer 45B are patterned to form the gate hard masks 47, the metal electrodes 46, and the second polysilicon electrodes 45C. The metal electrodes 46 may include one of tungsten and tungsten silicide.

The first and second polysilicon electrodes 45A and 45C may be formed without generating voids because a portion of the bottom recesses 43B is filled with the first polysilicon electrodes 45A using the deposition method, and the rest of the bottom recesses 43B and the upper recesses 43A are filled with the second polysilicon electrodes 45C using the SEG method growing silicon.

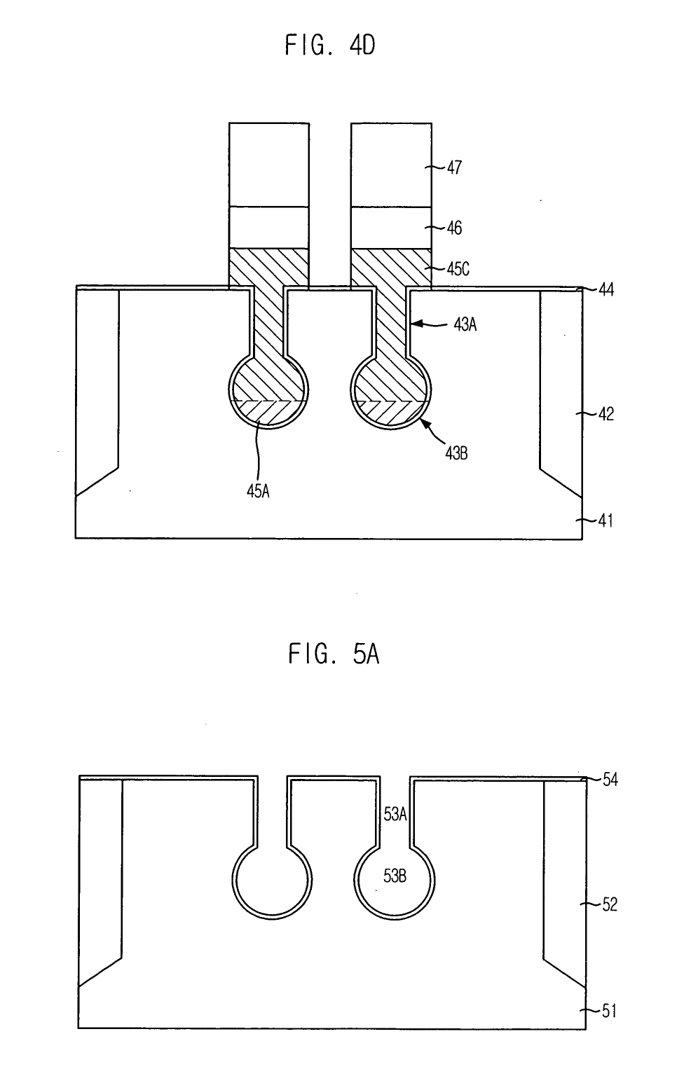

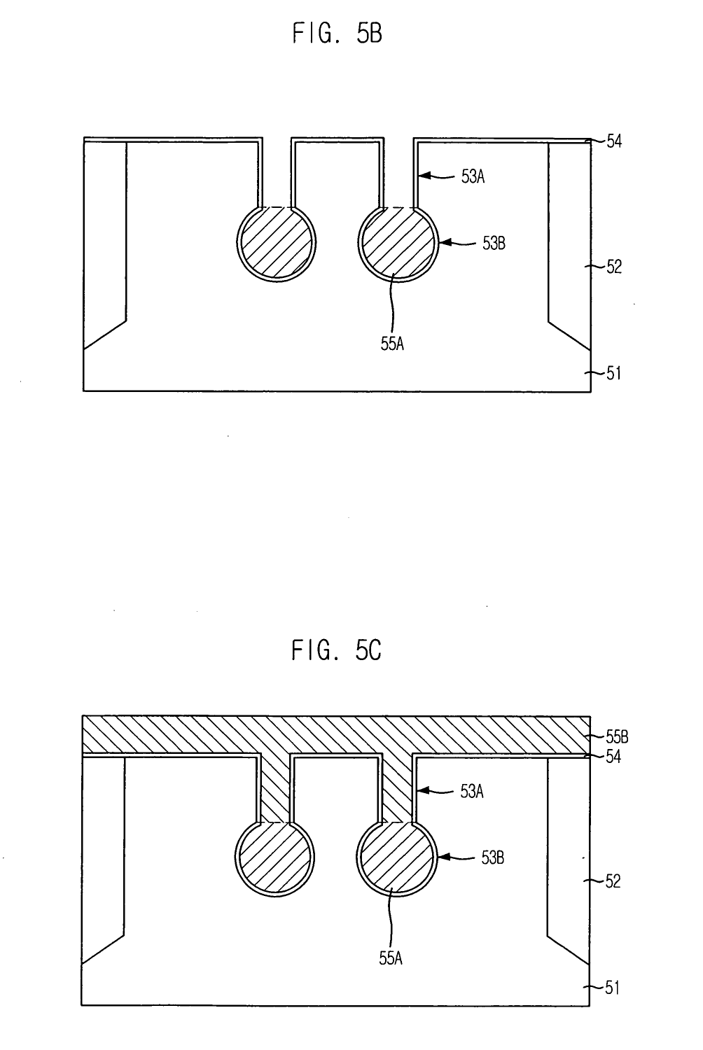

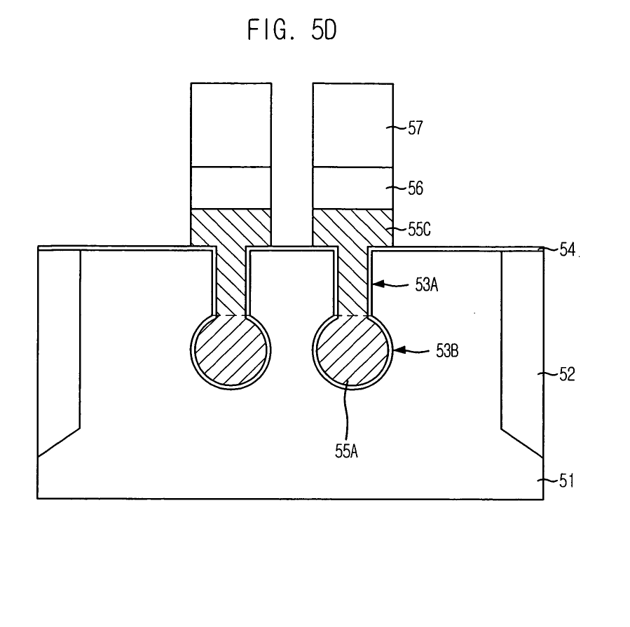

FIGS. 5A to 5D illustrate cross-sectional views to describe a method for fabricating a semiconductor device consistent with a fourth embodiment of the present invention.

Referring to FIG. 5A, device isolation structures 52 are formed in a substrate 51. The device isolation structures 52 are formed to define an active region and have a larger depth than subsequent recesses. Portions of the substrate 51 are selectively etched to form bulb type recesses. The bulb type recesses have a vertical profile, and each bulb type recess is configured with an upper recess 53A and a bottom recess 53B. Each bottom recess 53B is formed in a round shape and has a larger width than the upper recess 53A. Forming the bottom recess 53B having the larger width than the upper recess 53A allows maintaining a longer channel length when compared to a typical ‘U’ type recess having substantially the same depth as the bulb type recess consistent with this embodiment. A gate insulation layer 54 is formed over the substrate 51 and the device isolation structures 52, and in the bulb type recesses.

Referring to FIG. 5B, first polysilicon electrodes 55A are filled in the bottom recesses 53B. The first polysilicon electrodes 55A are formed by performing a solid phase epitaxy (SPE) method. Performing the SPE method includes forming a silicon seed layer and growing the silicon seed layer.

Thus, the first polysilicon electrodes 55A may be formed in the bottom recesses 53B without generating voids by growing a seed layer unlike typical deposition methods often generating voids due to a depth or width.

Referring to FIG. 5C, a second polysilicon electrode layer 55B is formed over the resultant substrate structure and filled in the upper recesses 53A. The second polysilicon electrode layer 55B is formed by performing an SEG method.

The second polysilicon electrode layer 55B is planarized. The second polysilicon electrode layer 55B, which is the uppermost layer of the resultant substrate structure, has an irregularly formed surface because a growth method, i.e., the SEG method, is employed, and thus, planarization is generally required.

Referring to FIG. 5D, gate patterns are formed, partially buried in the upper and bottom recesses 53A and 53B. Each gate pattern is configured with a gate hard mask 57, a metal electrode 56, a second polysilicon electrode 55C, and the first polysilicon electrode 55A. In more detail, a metal electrode layer and a gate hard mask layer are sequentially formed over the second polysilicon electrode layer 55B. The gate hard mask layer includes a nitride-based material. The gate hard mask layer, the metal electrode layer, and the second polysilicon electrode layer 55B are patterned to form the gate hard masks 57, the metal electrodes 56, and the second polysilicon electrodes 55C. The metal electrodes 56 may include one of tungsten and tungsten silicide.

A sufficient level of deposition margin is maintained because the first polysilicon electrodes 55A are formed in the bottom recesses 53B in advance using the SPE method, and the second polysilicon electrodes 55C are also formed by performing a growth method, i.e., the SEG method. Consequently, the first and second polysilicon electrodes 55A and 55C may be formed without generating voids.

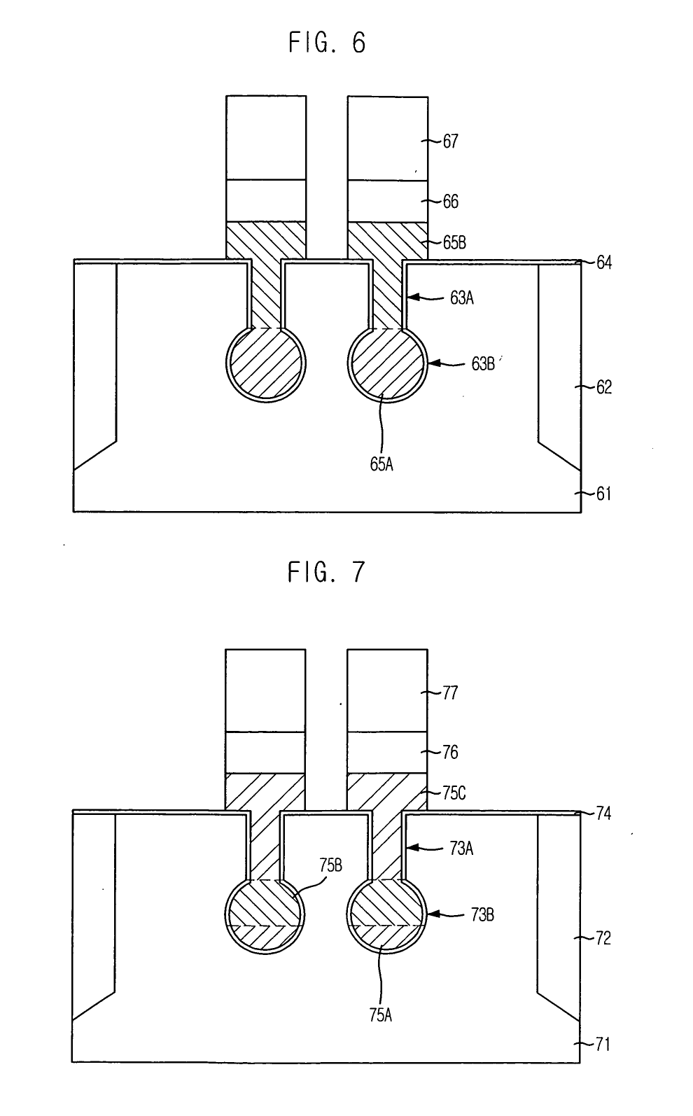

FIGS. 6 to 9 illustrate cross-sectional views of a semiconductor device consistent with an embodiment of the present invention.

Referring to FIG. 6, a semiconductor device consistent with the first embodiment is illustrated. That is, the semiconductor device is formed in accordance with the semiconductor device described in FIGS. 2A to 2D. Device isolation structures 62 are formed in a substrate 61. Portions of the substrate 61 are selectively etched to form bulb type recesses. Each bulb type recess is configured with an upper recess 63A and a bottom recess 63B. Each bottom recess 63B is formed in a round shape and has a larger width than the upper recess 63A. A gate insulation layer 64 is formed over the substrate 61 and the device isolation structures 62, and in the bulb type recesses.

Gate patterns are formed, partially buried in the upper and bottom recesses 63A and 63B. In more detail, first polysilicon electrodes 65A are filled in the bottom recesses 63B using a SPE method, and a second polysilicon electrode layer is formed over the substrate structure and filled in the upper recesses 63A using a CVD method. A metal electrode layer and a nitride-based gate hard mask layer are sequentially formed over the second polysilicon electrode layer. The nitride-based gate hard mask layer, the metal electrode layer, and the second polysilicon electrode layer are patterned to form gate hard masks 67, metal electrodes 66, and second polysilicon electrodes 65B. Consequently, the gate patterns are formed.

Forming the polysilicon electrodes by combining the SPE method, which is a growth method, and the CVD method, which is a deposition method, allows the polysilicon electrodes to be formed without voids while securing a deposition margin and omitting a planarization process.

Referring to FIG. 7, a semiconductor device consistent with the second embodiment is illustrated. That is, the semiconductor device is formed in accordance with the semiconductor device described in FIGS. 3A to 3E. Device isolation structures 72 are formed in a substrate 71. Portions of the substrate 71 are selectively etched to form bulb type recesses. Each bulb type recess is configured with an upper recess 73A and a bottom recess 73B. Each bottom recess 73B is formed in a round shape and has a larger width than the upper recess 73A. A gate insulation layer 74 is formed over the substrate 71 and the device isolation structures 72, and in the bulb type recesses.

Gate patterns are formed, partially buried in the upper and bottom recesses 73A and 73B. In more detail, first polysilicon electrodes 75A are filled in a portion of the bottom recesses 73B using a CVD method. Second polysilicon electrodes 75B are formed to fill the rest of the bottom recesses 73A using a SPE method. A third polysilicon electrode layer is formed over the substrate structure and filled in the upper recesses 73A using a CVD method. A metal electrode layer and a nitride-based gate hard mask layer are sequentially formed over the third polysilicon electrode layer. The nitride-based gate hard mask layer, the metal electrode layer, and the third polysilicon electrode layer are patterned to form gate hard masks 77, metal electrodes 76, and third polysilicon electrodes 75C. Consequently, the gate patterns are formed.

Forming the polysilicon electrodes by combining two steps of the CVD method, which is a deposition method, and one step of the SPE method, which is a growth method, allows the polysilicon electrodes to be formed without voids while securing a deposition margin and omitting a planarization process.

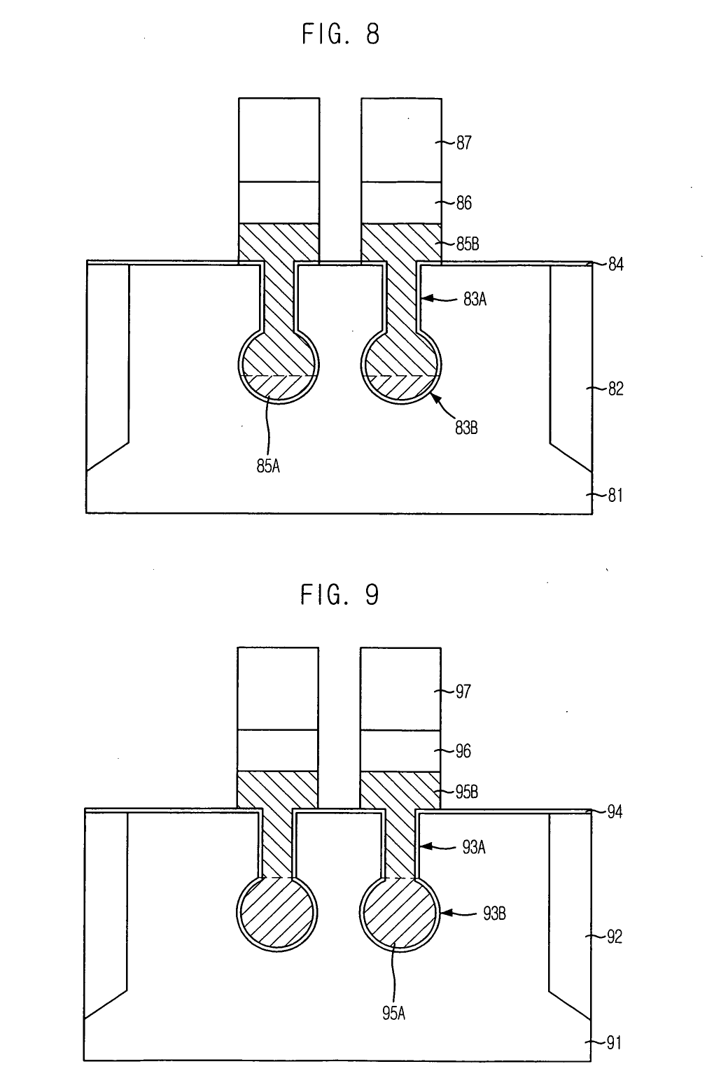

Referring to FIG. 8, a semiconductor device consistent with the third embodiment is illustrated. That is, the semiconductor device is formed in accordance with the semiconductor device described in FIGS. 4A to 4D. Device isolation structures 82 are formed in a substrate 81. Portions of the substrate 81 are selectively etched to form bulb type recesses. Each bulb type recess is configured with an upper recess 83A and a bottom recess 83B. Each bottom recess 83B is formed in a round shape and has a larger width than the upper recess 83A. A gate insulation layer 84 is formed over the substrate 81 and the device isolation structures 82, and in the bulb type recesses.

Gate patterns are formed, partially buried in the upper and bottom recesses 83A and 83B. In more detail, first polysilicon electrodes 85A are filled in a portion of the bottom recesses 83B using a CVD method, and a second polysilicon electrode layer is formed over the substrate structure and filled in the rest of the bottom recesses 83B and the upper recesses 83A using a SEG method. A metal electrode layer and a nitride-based gate hard mask layer are sequentially formed over the second polysilicon electrode layer. The nitride-based gate hard mask layer, the metal electrode layer, and the second polysilicon electrode layer are patterned to form gate hard masks 87, metal electrodes 86, and second polysilicon electrodes 85B. Consequently, the gate patterns are formed.

Forming the polysilicon electrodes by combining the CVD method, which is a deposition method, and the SEG method, which is a growth method, allows the polysilicon electrodes to be formed without voids.

Referring to FIG. 9, a semiconductor device consistent with the fourth embodiment is illustrated. That is, the semiconductor device is formed in accordance with the semiconductor device described in FIGS. 5A to 5D. Device isolation structures 92 are formed in a substrate 91. Portions of the substrate 91 are selectively etched to form bulb type recesses. Each bulb type recess is configured with an upper recess 93A and a bottom recess 93B. Each bottom recess 93B is formed in a round shape and has a larger width than the upper recess 93A. A gate insulation layer 94 is formed over the substrate 91 and the device isolation structures 92, and in the bulb type recesses.

Gate patterns are formed, partially buried in the upper and bottom recesses 93A and 93B. In more detail, first polysilicon electrodes 95A are filled in the bottom recesses 93B using a SPE method, and a second polysilicon electrode layer is formed over the substrate structure and filled in the upper recesses 93A using a SEG method. A metal electrode layer and a nitride-based gate hard mask layer are sequentially formed over the second polysilicon electrode layer. The nitride-based gate hard mask layer, the metal electrode layer, and the second polysilicon electrode layer are patterned to form gate hard masks 97, metal electrodes 96, and second polysilicon electrodes 95B. Consequently, the gate patterns are formed.

Forming the polysilicon electrodes by combining the SPE method and the SEG method, which are both growth methods, allows the polysilicon electrodes to be formed without voids.

Consistent with the embodiments of this invention, the polysilicon electrodes can be formed in the bulb type recesses without generating voids by combining deposition and growth methods, for instance, combining the CVD method, the SPE method, and the SEG method.

A stress point may be removed and device reliability may be improved by removing voids in the bulb type recesses.

The present application contains subject matter related to the Korean patent application No. KR 2006-0019682, filed in the Korean Patent Office on Feb. 28, 2006, the entire contents of which being incorporated herein by reference.

While the present invention has been described with respect to certain specific embodiments, it will be apparent to those skilled in the art that various changes and modifications may be made without departing from the spirit and scope of the invention as defined in the following claims.

What is claimed is:

1. A semiconductor device, comprising:
a substrate;
a bulb type recess with an upper recess and a bottom recess, the bottom recess formed in a round shape and having a larger width than the upper recess;
a gate insulation layer formed over the substrate and in the bulb type recess; and
a polysilicon electrode in the bulb type recess, wherein the polysilicon electrode is formed using two different methods including a growth method.

2. The semiconductor device of claim 1, wherein a bottom portion of the polysilicon electrode is formed by performing a solid phase epitaxy method, and an upper portion of the polysilicon electrode is formed by performing a chemical vapor deposition method.

3. The semiconductor device of claim 1, wherein a bottom portion of the polysilicon electrode is formed by performing a chemical vapor deposition (CVD) method, a middle portion of the polysilicon electrode is formed by performing a solid phase epitaxy method, and an upper portion of the polysilicon electrode filled is formed by performing a CVD method.

4. The semiconductor device of claim 1, wherein a bottom portion of the polysilicon electrode is formed by performing a chemical vapor deposition method, and an upper portion of the polysilicon electrode is formed by performing a selective epitaxial growth method.

5. The semiconductor device of claim 1, wherein an upper portion of the polysilicon electrode is formed by performing a solid phase epitaxy method, and an upper portion of the polysilicon electrode is formed by performing a selective epitaxial growth method.

6. A method for fabricating a semiconductor device, comprising:
selectively etching a portion of a substrate to form a bulb type recess with an upper recess and a bottom recess, the bottom recess formed in a round shape and having a larger width than the upper recess;
forming a gate oxide layer over the substrate and in the bulb type recess; and
forming a polysilicon electrode in the bulb type recess using two different types of methods including a growth method.

7. The method of claim 6, wherein forming the polysilicon electrode comprises:
forming a first polysilicon layer in the bottom recess by performing a solid phase epitaxy method; and
forming a second polysilicon layer in the upper recess by performing a chemical vapor deposition method.

8. The method of claim 6, wherein forming the polysilicon electrode comprises:
forming a first polysilicon layer in a portion of the bottom recess by performing a chemical vapor deposition (CVD) method;
forming a second polysilicon layer in the rest of the bottom recess by performing a solid phase epitaxy method; and
forming a third polysilicon layer in the upper recess by performing a CVD method.

9. The method of claim 6, wherein forming the polysilicon electrode comprises:
forming a first polysilicon layer in a portion of the bottom recess by performing a chemical vapor deposition method; and
forming a second polysilicon layer in the rest of the bottom recess and the upper recess by performing a selective epitaxial growth method.

10. The method of claim 6, wherein forming the polysilicon electrode comprises:
forming a first polysilicon layer in the bottom recess by performing a solid phase epitaxy method; and
forming a second polysilicon layer in the upper recess by performing a selective epitaxial growth method.

11. The method of claim 6, further comprising, after forming the polysilicon electrode, forming a metal electrode and a nitride-based gate hard mask over the polysilicon electrode and patterning the metal electrode and the nitride-based gate hard mask to form a gate pattern.
